(19) United States
(12) Patent Application Publication
(10) Pub. No.: US 2019/0321666 A1
(43) Pub. Date: Oct. 24, 2019

(54) SYSTEMS AND METHODS FOR REDUCING SMOKE RELEASE OF PRINTED CIRCUIT BOARDS IN BUILDING AIR HANDLING SPACE PRODUCTS

(71) Applicant: Johnson Controls Technology Company, Auburn Hills, MI (US)

(72) Inventors: Wesley J. Irek, Oak Creek, WI (US); Toni M. Ruel, Milwaukee, WI (US); Christopher Brophy, Cedarburg, WI (US); Gerald P. Nagl, Menomonee Falls, WI (US)

(73) Assignee: Johnson Controls Technology Company, Auburn Hills, MI (US)

(21) Appl. No.: 16/387,296

(22) Filed: Apr. 17, 2019

Related U.S. Application Data
(60) Provisional application No. 62/659,419, filed on Apr. 18, 2018.

(51) Int. Cl. A62C 3/02; A62C 2/06; H05K 1/02

(52) U.S. Cl. CPC A62C 3/0214; H05K 1/0201; A62C 2/065

(57) ABSTRACT

A method for reducing smoke in a building fire includes integrating a non-halogen flame retardant into a printed circuit board, installing the printed circuit board in an electronic device, and installing the electronic device in an air handling space.

### CROSS-REFERENCE TO RELATED APPLICATION

This application claims the benefit of and priority to U.S. Provisional Patent Application No. 62/659,419, filed Apr. 18, 2018, the entire disclosure of which is incorporated by reference herein.

### BACKGROUND

The present disclosure relates generally to the field of electronic devices for use in building air handling spaces (i.e., air handling spaces such as drop ceilings, hollow floors, ductwork, etc.) or in air handling equipment. More particularly, the present disclosure relates to reducing the amount of smoke given off by electronic devices in building air handling spaces or air handling equipment in the event of fire.

Electronic devices such as equipment controllers, lighting devices, security devices, cameras, speakers, network devices, etc. are often located in air handling spaces of buildings to provide controls, networking capabilities, or other functions for the building. In the event of a fire in the building, these electronic devices may burn and give off smoke. Because the electronic devices are located in building air handling spaces (e.g., air handling spaces that facilitate air flow in a building, the smoke emitted by the electronic devices may quickly spread through the building). Heavy, dark smoke given off by an electronic device in a building air handling space may therefore impair visibility for occupants trying to escape the building and prevent or hinder escape.

Electronic devices for building air handling spaces may therefore be required to conform to industry standards and/or pass one or more tests in order to be approved for use. One such standard is Underwriters Laboratories (UL) 2043 (“UL2043”), which defines a test procedure and pass/fail criteria for smoke density and heat release for electronic devices used in building air handling spaces. In the test, the device being tested is completely engulfed in a 1 ft×1 ft flame for ten minutes, to simulate a building fire. The smoke given off enters an 8 ft×8 ft smoke collector. Peak smoke density, average smoke density, and peak heat release are measured. To pass the test (i.e., to prove that a device conforms with the standard), the peak smoke density must be 50% or less, the average smoke density must be 15% or less, and the peak heat release must be 100 kW or less. A failure of one of the criteria is a failure for the entire test. Notably, existing electronic devices for building air handling spaces typically produce too much smoke and fail the test. Many such products were grandfathered into the standards regime and do not conform to the UL2043 standard. Typical electronic devices thus give off an unsafe level of smoke and may endanger the safety of building occupants in the event of a building fire.

Electrical code provisions such as Section 300.22 of the National Electrical Code by the National Fire Protection Association require that, for the sake of smoke-release reduction, electrical equipment in building air handling spaces must include a metal enclosure or a nonmetallic enclosure “having low smoke and heat release properties,” for example as established using the UL2043 standard outlined above. It should be noted that this and other safety code provisions are focused on characteristics of enclosures in which electronic components such as printed circuit boards may be housed. That is, regulators, standards organizations, and industry currently focus solely on the enclosure in determining whether an electronic device is safe for installation in an air handling space. Manufacturers may make various decisions relating to materials and designs for such enclosures to attempt to satisfy the standards.

Accordingly, improved systems and methods for reducing the smoke emissions of electronic devices used in building air handling spaces are needed in order to facilitate the creation of new electronic devices that meet the UL2043 standard and to improve the safety of burning buildings

### SUMMARY

One implementation of the present disclosure is a method for reducing smoke in a building fire. The method includes integrating a non-halogen flame retardant into a printed circuit board, installing the printed circuit board in an electronic device, and installing the electronic device in an air handling space.

In some embodiments, the non-halogen flame retardant includes phosphorous. In some embodiments, the method includes at least partially covering the printed circuit board in an intumescent coating. In some embodiments, the method includes at least partially surrounding the printed circuit board with intumescent sheets.

In some embodiments, installing the electronic device in the air handling space includes positioning the printed circuit board in the air handling space such that the printed circuit board is exposed to airflow in the air handling space. In some embodiments, installing the printed circuit board in an electronic device includes placing the printed circuit board in a plastic enclosure.

In some embodiments, the electronic device is a lighting device. In some embodiments, the method includes establishing communication between the electronic device and HVAC equipment and operating the electronic device to control the HVAC equipment. In some embodiments, the electronic device includes one or more of a lighting device, an HVAC device, a security device, a fire device, a speaker, or a camera.

In some embodiments, the air handling space is within a rooftop unit of an HVAC system. In some embodiments, the air handling space is above a drop ceiling or below a raised floor.

Another implementation of the present disclosure is a method for reducing smoke release in a building fire. The method includes obtaining a printed circuit board. The printed circuit board includes a non-halogen frame retardant or is at least partially covered with an intumescent coating or an intumescent sheet. The method also includes configuring circuitry components of the printed circuit board to perform one or more operations relating to a building and installing the printed circuit board in an air handling space.

In some embodiments, the method also includes operating the circuitry components of the printed circuit board to perform the operations. In some embodiments, the one or more operations comprise controlling, by the printed circuit board, HVAC equipment. In some embodiments, the one or more operations comprise providing, by the printed circuit board, wireless network connectivity to user devices in a space proximate the air handling space. In some embodiments, the one or more operations comprise controlling, by the printed circuit board, at least one of a speaker to emit a sound or a light fixture to emit a light.

In some embodiments, installing the printed circuit board in the air handling space includes positioning the printed circuit board such that the printed circuit board is at least partially exposed to airflow in the air handling space. In some embodiments, the printed circuit board is at least partially surrounded with a plurality of intumescent sheets.

Another implementation of the present disclosure is a system. The system includes an air handling space and a printed circuit board at least partially exposed to airflow in the air handling space. The printed circuit board includes at least one of a non-halogen flame retardant, an intumescent coating, or an intumescent sheet.

In some embodiments, the system includes a drop ceiling and an electronic device coupled to the drop ceiling, the air handling space is at least partially bounded by the drop ceiling, and the printed circuit board is configured to facilitate operation of the electronic device.

### BRIEF DESCRIPTION OF THE DRAWINGS

FIG. 1A is an illustration of a controller installed in a air handling space of a building, according to some embodiments.

FIG. 1B is an illustration of a controller installed within an air handling space of building equipment that serves the building, according to some embodiments.

FIG. 2 is an illustration of an experimental setup for testing the smoke released from a printed circuit board engulfed in flame, according to some embodiments.

FIG. 3 is a graph illustrating the smoke release of a typical existing printed circuit board engulfed in flame, according to some embodiments.

FIG. 4 is a graph illustrating the smoke release of printed circuit boards of various materials, according to some embodiments.

FIG. 5 is a graph illustrating the smoke release of printed circuit boards with various layers of intumescent coating, according to some embodiments.

FIG. 6 is a graph illustrating the smoke release of printed circuit boards covered with intumescent sheets, according to some embodiments.

FIG. 7 is a diagram of a building with multiple printed circuit boards installed in multiple air handling spaces, according to an exemplary embodiment.

FIG. 8 is a diagram of a rooftop unit with a printed circuit board, according to an exemplary embodiment.

FIG. 9 is a diagram of electronic devices with metal enclosures positioned in an air handling space, according to an exemplary embodiment.

FIG. 10 is a diagram of electronic devices with plastic enclosures positioned in an air handling space, according to an exemplary embodiment.

FIG. 11 is a diagram of printed circuit boards mounted in an air handling space, according to an exemplary embodiment.

### DETAILED DESCRIPTION

The systems and methods described herein reduce the amount and/or opaqueness of smoke released in a building fire, facilitating an occupant of the building in reaching safety. In particular, the systems and methods described reduce the amount of visibility-reducing smoke released by electrical devices in air handling spaces of the building, helping to preserve visibility in the building during a fire.

As detailed above, when evaluating smoke safety for electrical devices in air handling spaces, current standards accepted by regulators and industry solely contemplate the composition and design of enclosures for the electrical devices. In contrast, the systems and methods described herein present a solution to the problem of smoke release by electrical devices in building plenums that can be achieved without a need for any enclosure and/or with the use of a lower-cost enclosure. As described in detail below, systems and methods relating to the printed circuit boards included in such devices can result in reduced smoke release and increased visibility to facilitate occupancy safety in the case of a building fire without addressing the conventional requirements for enclosures as detailed by existing standards and tests. The current standards do not consider the possibility of—and may discourage—such a solution. In fact, the systems and methods described herein may require changes to such standards and tests to allow for and/or require use of the advantageous solutions presented herein.

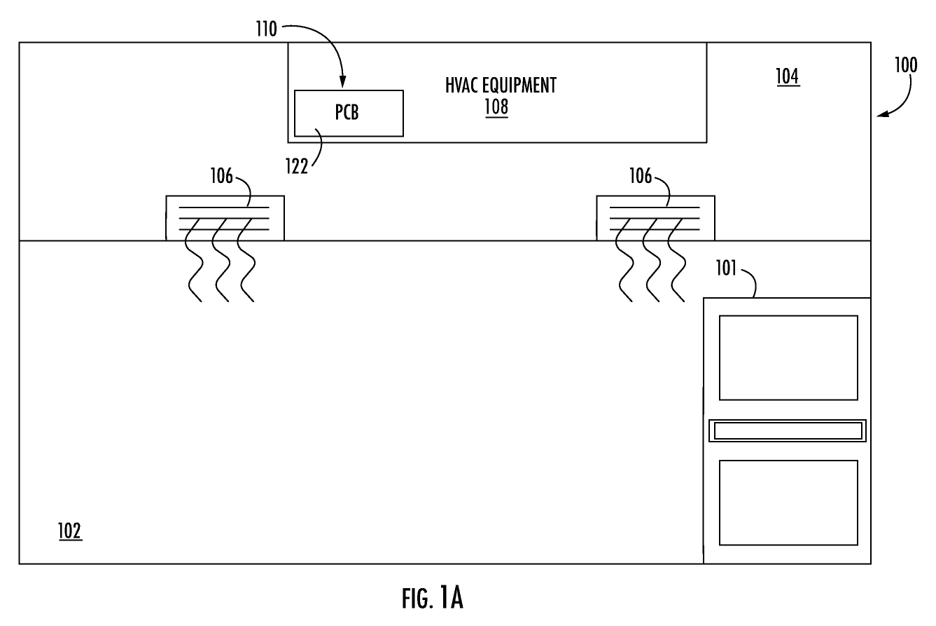

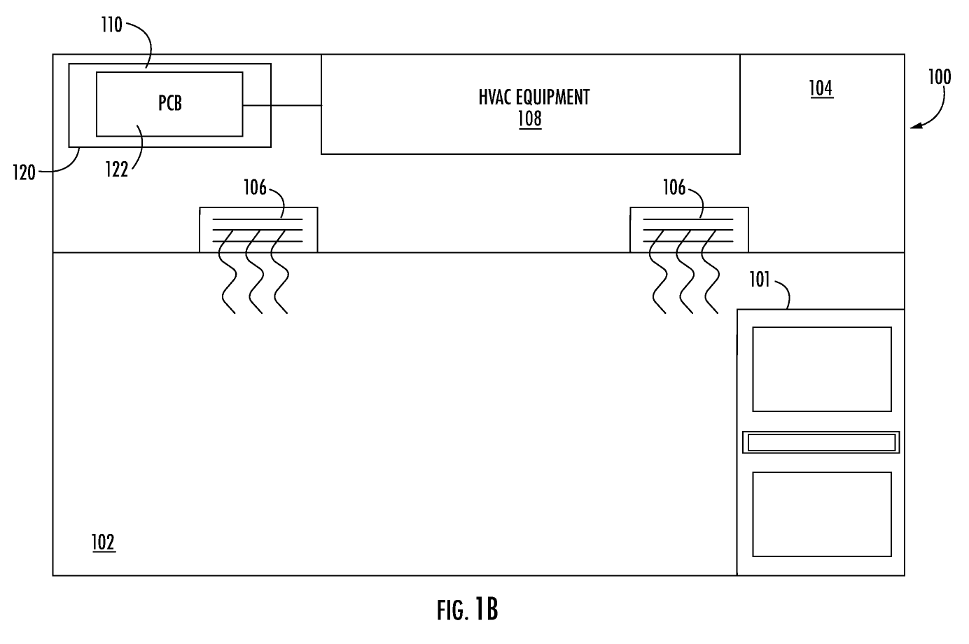

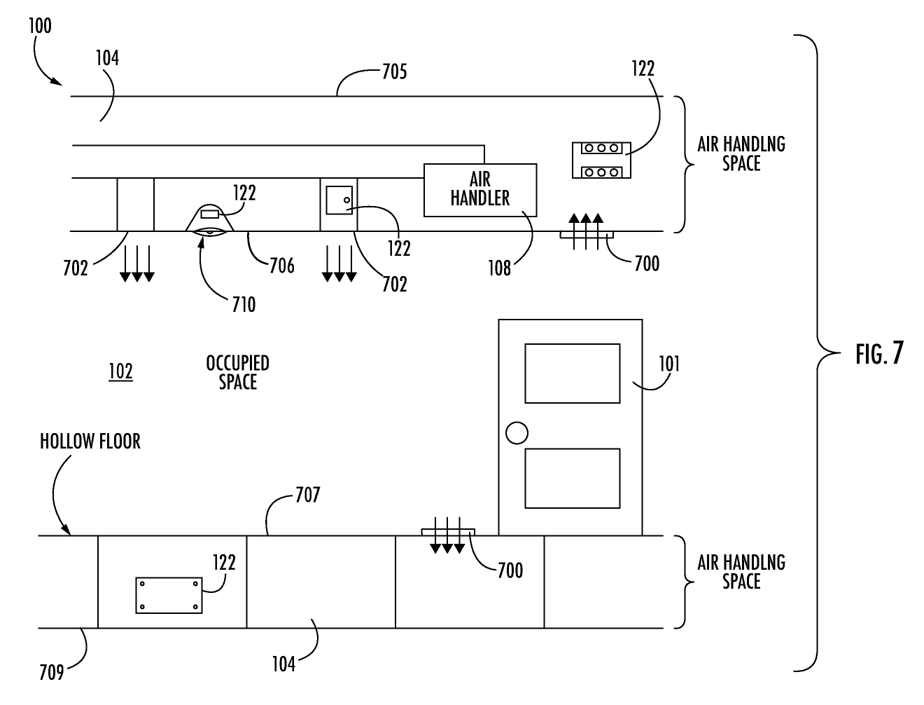

Referring to FIGS. 1A-B, an illustration of a building 100 with a room 102 and an air handling space 104 is shown, according to an exemplary embodiment. The room 102 has an exit 101, through which an occupant of the room 102 may need to escape in event of a fire. FIGS. 1A-B show example configurations suitable for use with the systems and methods described herein. Further examples are shown in FIGS. 7-11 and described in detail with reference thereto below.

Air handling space 104 (e.g., ductwork) provides air handling for the building 100, including providing airflow into or out of room 102 of building 100. Air handling space 104 may facilitate the heating or cooling of the room 102 by facilitating the flow of hot or cold air into the room 102 via vents 106. In some cases, air handling space 104 may also provide ventilation out of the room 102. Accordingly, air handling space 104 may house HVAC equipment 108 and/or otherwise receive airflow from HVAC equipment 108. The HVAC equipment 108 may include an air handling unit, variable air volume box, variable refrigerant flow unit, ventilation fan, air conditioning unit, etc. Accordingly, the HVAC equipment 108 may include one or more actuators (e.g., electronically-controllable dampers, valves, fans, etc.) that can be controlled to alter characteristics (e.g., air flow rate, temperature, etc.) of heating, cooling, or ventilation provided to the room 102.

In the examples shown, the equipment 108 is located in the building 100. In other embodiments, the equipment 108 is located outside the building 100 (e.g., on a roof of the building 100) in pneumatic communication with the air handling space 104 (e.g., such that air can flow from the equipment 108 to the room 102).

A controller 110 is included and is communicable coupled with the HVAC equipment 108. In the example of FIG. 1A, the controller 110 is located in the HVAC equipment. In the example of FIG. 1B, the controller 110 is positioned in the air handling space 104 (i.e., outside of the equipment 108). The controller 110 generates a control signal for the equipment 108 and/or controls an actuator included with the controller 110. The controller 110 may be configured specifically for installation in an air handling space, for example by including specialty mounts or other couplings suited for used in an air handling space. As described in detail below, the controller 110 is also configured to minimize smoke emitted from the controller 110 when the controller 110 is engulfed in flame (i.e., in a building fire). It should be understood that while controller 110 is used herein as an example of electronic device that may be installed in the air handling space 104, many other electronic devices may also be installed in an air handling space and fall within the scope of the present disclosure (e.g., in-ceiling speakers, sound system electronics, in-ceiling light fixture controls). In either case, the controller 110 is positioned in or adjacent (e.g., at a boundary of) and airway that allows air to flow through or from the HVAC equipment 108 to the room 102 (e.g., via the air handling space 104).

In the embodiment shown in FIG. 1B, the controller 110 includes a case 120 that protects the various components of the controller 110. Most conventional approaches to reducing flammability and smoke emissions of the controller 110 (or other electronic devices) focus on the design of the case 120, for example by designing the case 120 in a way intended to protect contents of the case 120 from flames and/or prevent smoke from escaping the case 120. The case 120 may be made of plastic and/or may include other materials (e.g., metals). Some embodiments described herein may provide a controller 110 or other electronic device without the case 120, achieving the goal of reduced flammability and smoke emissions without relying on the conventional, standardized solution of a case 120. For example, as shown in FIG. 1A, the controller 110 is positioned in the HVAC equipment 108 without a case.

For decades, UL has considered the polymeric composition of the case 120 as the major contributing factor to determining smoke emissions from products declared to be installed in air handling spaces. For example, some UL standards allow for exemptions to burn testing based on the amount of polymeric material in the product. However, the present disclosure makes an unexpected and revolutionary switch in focus to redesigning the PCB 122 to achieve smoke emissions standards. Notably, during tests of smoke emissions, the case 120 burns but typically emits smoke at a level well below the test limits.

The controller 110 also includes a printed circuit board (PCB) 122. The PCB 122 includes a circuit board substrate on which circuitry is mounted/printed/installed/etc. The circuitry is operable to provide data processing and/or data storage for the controller 110 (e.g., to generate control signals for the equipment 108). According to various embodiments, the PCB 122 includes various layers of fiberglass, copper, and epoxy ‘sandwiched’ together (i.e., coupled together in abutting layers). In some cases, the PCB 122 also includes a conformal coating. The conformal coating is an epoxy resin that may be applied to the PCB 122 to protect against damage from environmental conditions such as heat and humidity and/or from corrosiveness or electrical conductivity of other materials in the controller 110. Conformal coatings are typically flammable. Notably, conventional approaches to fire safety engineering for electronic devices for building air handling spaces such as controller 110 have largely ignored the material composition of the PCB 122.

In the case of a fire in the building 100 and the air handling space 104, the fire may cause the controller 110 to burn and emit smoke. Smoke emitted from the controller 110 flows through the air handling space 104 and into the room 102. Because the air handling space 104 may be designed to provide airflow to the room 102, the air handling space may also efficiently and quickly provide for the flow of the smoke from the burning controller 110 into the room 102. If the controller 110 emits a high amount of smoke, the smoke may therefore flood the room 102 and prevent an occupant from finding and/or reaching exit 101.

Thus, minimizing the amount of smoke emitted by the controller 110 is an important objective. Notably, experimental observations show that the PCB 122 contributes substantially more smoke in the UL2043 test than the case 120. Conventional approaches to smoke reduction focus on the design of the case 120 to protect the PCB 122 from flames. The present disclosure, however, innovatively focuses improvements to the PCB 122 itself that reduce smoke emissions of the PCB 122, and, accordingly, reduce smoke emissions of the controller 110.

To address the challenge of high smoke emissions for the PCB 122, various embodiments of the PCB 122 are contemplated by the present disclosure. In some embodiments, the PCB 122 includes a non-halogen flame retardant. The non-halogen flame retardant may be a phosphorus-based flame retardant. When exposed to flames, the phosphorous flame retardant produces a condensed char layer that prevents any further burning of the PCB 122. Smoke release is therefore limited, as the PCB 122 does not burn and release smoke. In some embodiments, a flame retardant (e.g., the non-halogen flame retardant) is included with a paper substrate or other substrate layered on the PCB 122. In some embodiments, the conformal coating is a phosphorus-based flame retardant conformal coating. In some embodiments, the PCB 122 includes a phosphorus-based flame retardant epoxy resin coating.

In some embodiments, the PCB 122 is painted with an intumescent coating. In some embodiments, a paper substrate or other substrate coated with an intumescent coating is included with the PCB 122. In some embodiments, the PCB 122 is coated with an intumescent coating by dipping the PCB 122 in the intumescent coating. In some embodiment, intumescent sheets are diecut and applied to both sides of the PCB 122. When exposed to flame, the intumescent coating or sheet swells to create a foam and/or char barrier which prevents burning while also providing insulation from heat. Smoke release is therefore limited, as the PCB 122 does not burn and release smoke.

It should be understood that the present disclosure also contemplates any combination of these embodiments. For example, the PCB 122 may both include a non-halogen flame retardant and be dipped in an intumescent coating. As another example, the PCB 122 may include a non-halogen flame retardant and be covered with intumescent sheets. As yet another example, the PCB 122 may be dipped in an intumescent coating and covered with intumescent sheets.

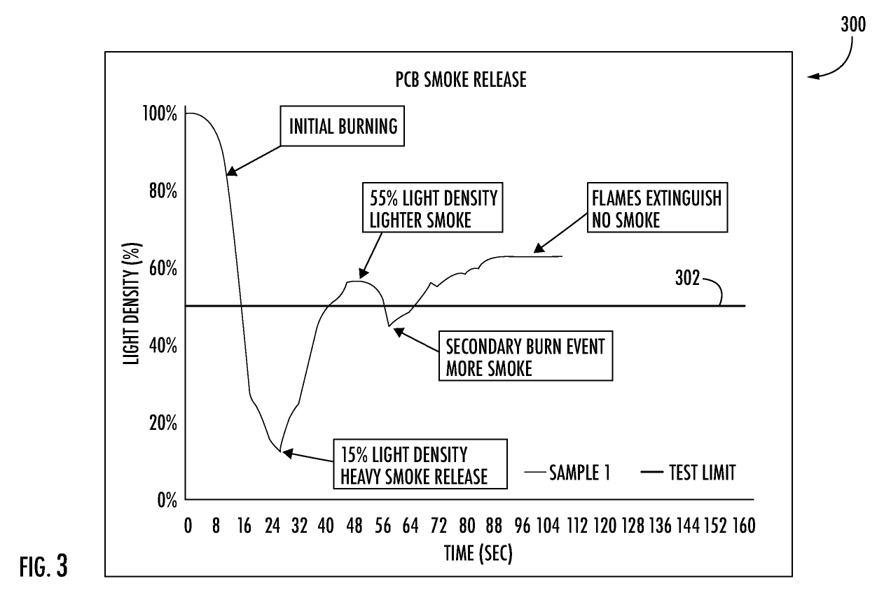

As described below with reference to FIGS. 3-6, the smoke emitted when the PCB 122 is exposed to flames is thereby substantially reduced. The controller 110 is thereby configured to pass the UL2043 test. Further, changes to the materials in the PCB 122 or an added coating for the PCB 122 may be implemented across all PCBs without requiring changes to the design of cases 120 for various electronic devices configured for installation in air handling spaces and/or allowing PCBs to be installed in air handling spaces without cases. Thus, the PCB-centric approach described herein offers a one-size-fits-all solution for electronic devices intended for use in building air handling spaces and targets the component most responsible for failure of the UL2043 test.

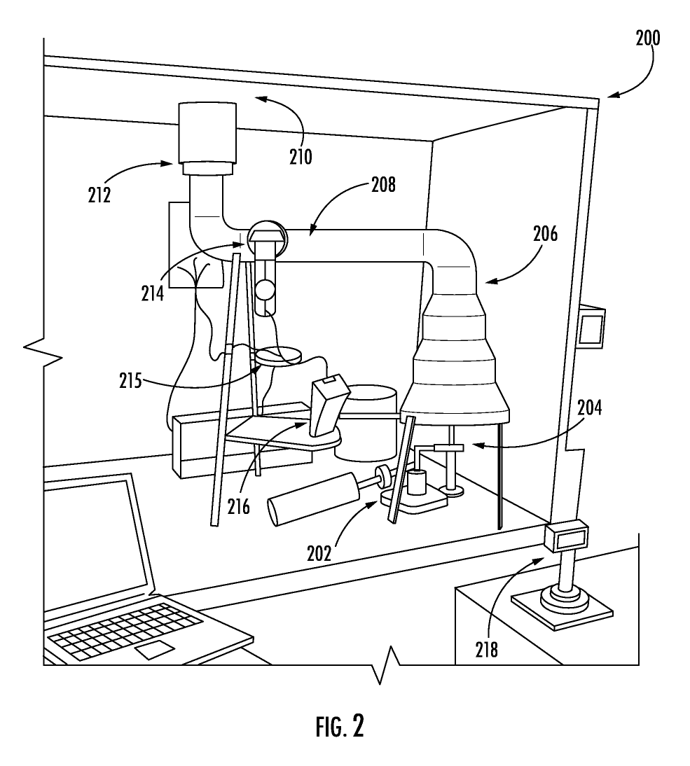

Referring now to FIG. 2, an experimental test setup 200 for testing the smoke emissions of PCBs is shown, according to an exemplary embodiment. The experimental test setup 200 includes flame source 202 positioned to expose a sample 204 (e.g., PCB 122) to a flame. A smoke collector 206 is positioned to collect smoke from the sample 204 and direct the smoke through a tube 208 to a fume hood 210. An exhaust fan 212 pulls the smoke through the smoke collector 206 and is positioned over the sample 204 to provide ventilation for smoke from the sample 204 through the smoke collector 206 and tube 208 and out through the fume hood 210. A lamp 215 is coupled to the tube 208 to shine across the smoke emitted from the sample 204 towards a light sensor 214. The light sensor 214 is coupled to the tube 208 and provides data to a light meter 216. The light meter 216 receives data from the light sensor 214 and tracks a light density percentage over time. The light density percentage quantifies the level of light measured by the light sensor 214 relative to a baseline, no-smoke level, such that the light density percentage decreases as the amount of smoke in the tube 208 increases (i.e., as the amount of smoke emitted by the sample 204 increases). A camera 218 records a video of each experiment. The experimental setup 200 is thereby configured to track light density percentage over time as each of various samples 204 are exposed to flames from the flame source 202.

Referring now to FIG. 3, a graph 300 of the light density percentage over time for a conventional PCB is shown, according to an example experiment. As shown by graph 300, a conventional PCB may emit smoke in a multi-stage process. The horizontal line 302 represents the 50% test limit of the UL2043 test. As the conventional PCB begins to burn, it gives off heavy black smoke that quickly exceeds the 50% limit and drops to around 15%. Then burning decreases as the board is consumed and there is less smoke. The light density rises to about 55%. Then, there is a small secondary burn event that is shown by the second drop below 50%, followed by a slow rise to steady state as the flames die out. Importantly, graph 300 shows a failure in the peak smoke density criteria of UL2043 caused by an uncontrolled burn of the PCB where the entire PCB burned at once.

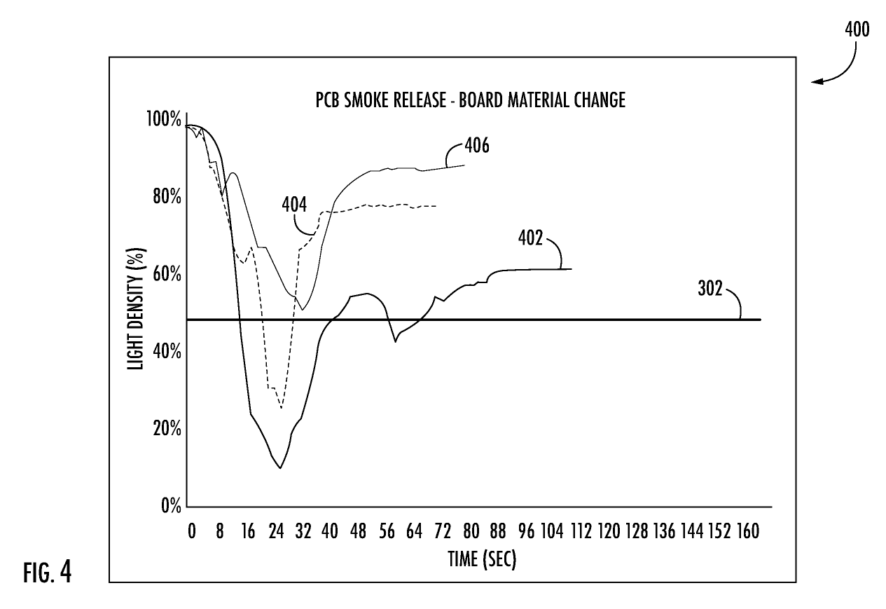

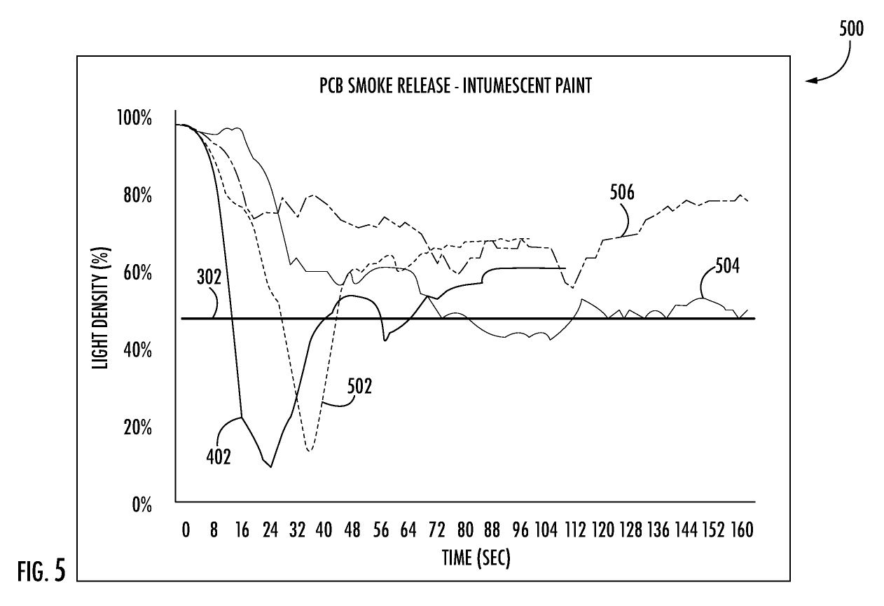

To pass the UL2043 test, the objective is to delay, limit, and/or prolong the burning of the PCB 122 to stay beneath the 50% peak smoke density limit indicated by horizontal line 302. Referring now to FIGS. 4 and 5, test results generated using the experimental test setup 200 for several embodiments of the PCB 122 are shown.

FIG. 4 shows a graph 400 experimental test results for two PCBs that include different materials than conventional PCBs. A first line 402 graphs the percentage light density over time for a conventional PCB, a second line 404 graphs the percentage light density over time for a PCB with FR-4 glass-reinforce epoxy laminate, and a third line 406 graphs the percentage light density over time for a PCB with a non-halogen flame-retardant material. The first line 402 corresponds to the result shown on graph 300 of FIG. 3.

The FR-4 laminate includes a halogen (e.g., bromine, fluorine, chlorine) for fire resistance. Halogen flame retardants inhibit vapor phase combustion, which may result in release of a heavy black smoke. The FR-4 laminate used to generate the experimental results represented by second line 404 has a glass transition temperature (Tg) of 140 C.

The non-halogen flame retardant of the third PCB 122 (i.e., the PCB corresponding to the third line 406) includes phosphorous. When exposed to flame, a phosphorous flame retardant produces a condensed char layer that prevents any further burning of the PCB 122. Because further burning of the PCB 122 is prevented, the secondary burn event observed for the conventional PCB 122 may be prevented. Further, the non-halogen flame retardant creates a char layer while producing relatively little smoke. In the embodiment tested, the non-halogen flame retardant is included in the PCB (i.e., incorporated in the material composition of the PCB).

As shown on the graph 400, the second line 404 is generally above the first line 402, and the third line 406 is generally above the second line 404. This indicates that the FR-4 PCB 122 performed better on the test than the conventional PCB 122, and the PCB 122 with the non-halogen flame-retardant material performed better than the FR-4 PCB 122. That is, the PCB 122 with the non-halogen flame retardant emitted the least amount of smoke. Furthermore, the first line 402 and the second line 404 cross the horizontal line 302, while the third line 406 does not. This indicates that the PCB 122 with the non-halogen flame retardant may conform to the UL2043 standard while the conventional PCB 122 and the FR-4 PCB 122 may not.

FIG. 5 graphs experimental test results for PCBs coated by intumescent coating using thee different methods. When exposed to flame, the intumescent coating swells to create a foam and/or char barrier which prevents burning while also providing insulation from heat. The intumescent coating may be applied to the PCB 122 in several manners. The intumescent coating may be brushed onto the PCB 122 or applied to a paper substrate coupled to the PCB 122. The PCB 122 may also be dipped in the intumescent coating. The intumescent coating may be sprayed onto the PCB 122, for example by diluting the intumescent coating with water (e.g., approximately 40% water, 60% intumescent coating). Multiple layers of intumescent coating may be provided (e.g., two layers, three layers, four layers). The intumescent coating provides one or more layers around the exterior of the PCB 122, and, in the event of fire, protects the PCB 122 from the heat and flames and prevents the PCB 122 from burning and emitting smoke.

FIG. 5 shows a graph 500 that includes the first line 402 from graph 400 (showing the light density percentage for the conventional PCB 122), a fourth line 502 that graphs the light density percentage over time for a PCB 122 with brushed-on intumescent coating, a fifth line 504 that graphs the light density percentage over time for a PCB 122 with a paper substrate coated with intumescent coating, and a sixth line 506 that graphs the light density percentage over time for a PCB 122 dipped in intumescent coating. Graph 500 shows that the brushed-on intumescent coating (fourth line 502) had relatively little effect on the smoke emission of the PCB 122 compared to the paper substrate with intumescent coating and the thicker coat of intumescent coating created by dipping the PCB 122 in the intumescent coating. The PCB 122 dipped in intumescent coating (sixth line 506) performed the best, emitting relatively little smoke in the experiment.

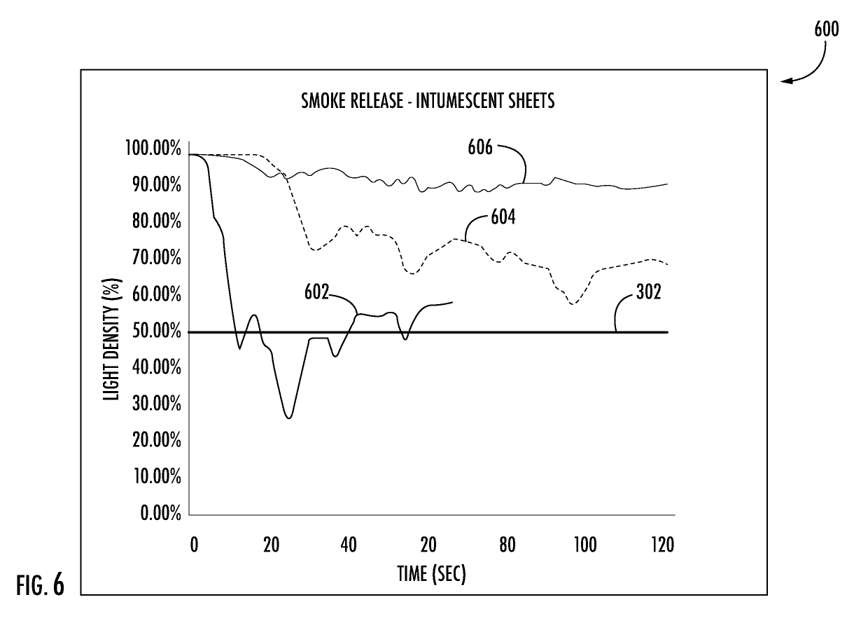

FIG. 6 illustrates experimental test results for PCBs covered (surrounded) by intumescent sheets in various thicknesses. As for the intumescent coating described above, the intumescent sheets swell to create a foam and/or char barrier which prevents burning while insulating the PCB 122 from heat. FIG. 6 shows a graph 600 that includes a seventh line 602 corresponding to a PCB 122 covered with intumescent sheets of a first thickness, an eighth line 604 corresponding to a PCB 122 covered with intumescent sheets of a second thickness which is thicker than the first thickness, and a ninth line 604 corresponding to a PCB 122 covered with intumescent sheets of a third thickness which is thicker than the second thickness. The seventh line 602 is substantially positioned below (i.e., in the direction of less light and more smoke) the eighth line 604 which is substantially positioned below the ninth line 606. The graph 600 thus illustrates that smoke release can be reduced by increasing the thickness of intumescent sheets covering (surrounding) the PCB 122. As illustrated by the eighth line 604 and the ninth line 606 remaining above the test limit 302 for the duration of the test shown on graph 600, such increases in thicknesses of intumescent sheets can be sufficient to satisfy the requirements of UL2043.

Thus, several of the PCBs 122 contemplated by the presented disclosure are well-suited for use in electronic devices for building air handling spaces. This unexpectedly and innovatively shifts the focus on reducing smoke emissions of such electronic devices from design of case 120 to the material composition of the PCBs 122. In addition to the improved benefits of flame retardance and reduced smoke emissions, managing smoke emissions by altering the material composition of the PCBs 122 rather than focusing on the design of the cases 120 allows the solution to be easily integrated into existing manufacturing processes and scaled across different sizes, shapes, and configurations of controllers without redesign of the plethora of various cases 120 and devices. The PCBs 122 of the present disclosure may allow the UL2043 standard to be changed so that a case 120 is no longer required and/or such that the UL2043 standard should be applied to PCBs mounted in an air handling space without a case or other enclosure. Further, shifting the focus of smoke emissions standards to the PCBs 122 from the cases 120 allows for a wider range of materials to be used in the cases 120, for example cheaper materials or materials that comply better with other standards, without compromising compliance with smoke emissions standards. Thus, use of non-halogen PCBs, intumescent-coated PCBs, and/or intumescent-sheet-covered PCBs in electronic devices configured for installation in building air handling spaces and other air handling spaces provide multiple advantageous benefits.

Referring now to FIG. 7, a diagram of a building 100 having multiple printed circuit boards 122 mounted in various air handling spaces 104 are shown, according to example embodiment. FIG. 7 is illustrative of several possible arrangements made possible by the systems and methods described herein.

As shown in FIG. 7, the building 100 includes an air handling space 104 located above an occupied space (room 102) and an air handling space 104 located below the occupied space. That is, the building 100 is shown to include a drop ceiling 706 that defines a space between the drop ceiling 706 and the structural ceiling 705, and a hollow floor defined by raised flooring 707 and structural floor 709. In the example shown, return air from the room 102 can flow into the air handling spaces 104 via return air vents 700. In the example shown, return air vents 700 are included with both the drop ceiling 706 and the raised floor 707. As shown in FIG. 7, air may also be provided to the room 102 from the air handling spaces 104 via ducts 702, for example via HVAC equipment 108 (shown as air handler 108 in FIG. 7).

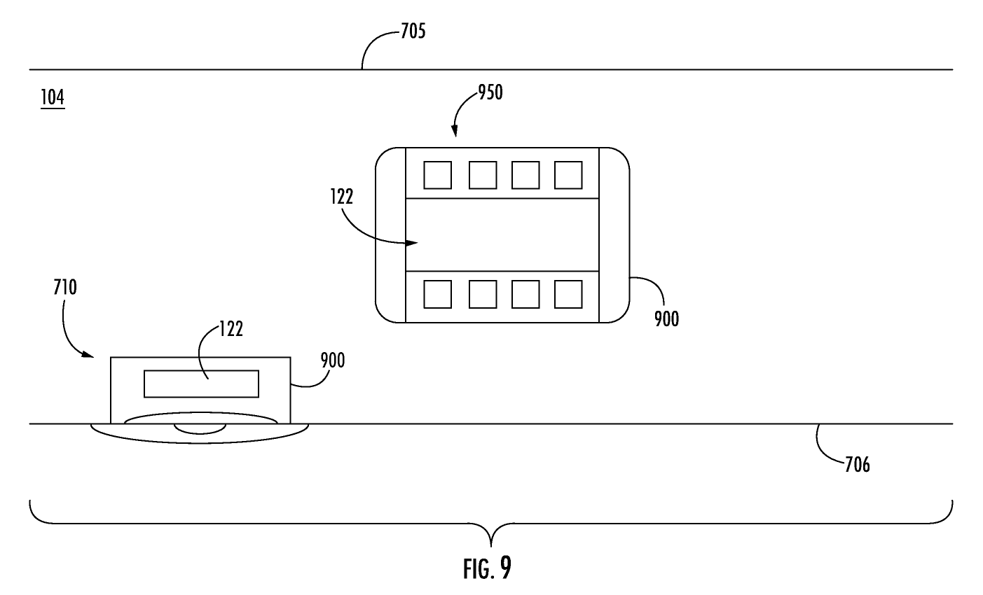

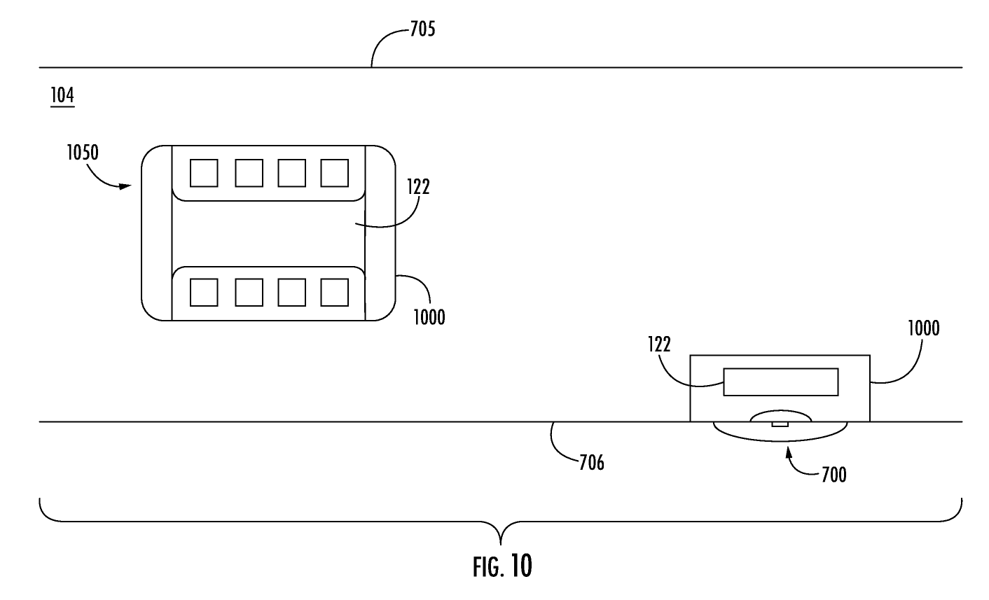

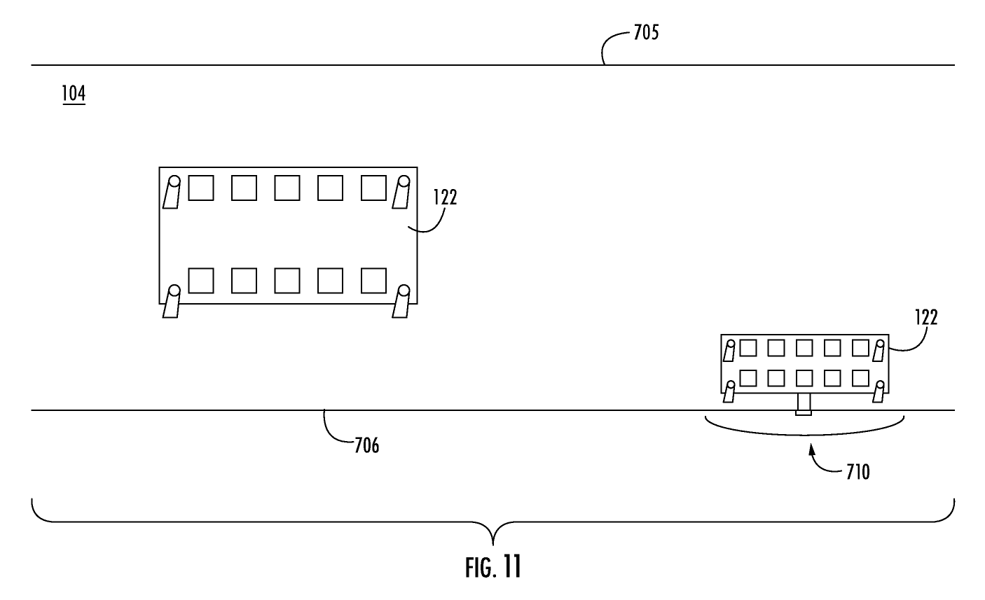

The present disclosure contemplates installation of printed circuit boards 122 in any such air handling space. In the example shown, a printed circuit board 122 is positioned between the structural floor 709 and the raised floor 707 and is exposed to airflow in the air handling space 704. In other words, the printed circuit board 122 is installed directly in the air handling space 704 without an enclosure (case). As described below with reference to FIG. 11, such an arrangement is made possible by the smoke-release properties of the printed circuit board 122 described above. As shown in FIG. 7, printed circuit boards 122 are shown as mounted in an enclosure and above the drop ceiling 706, both as stand-alone electrical devices and as part of a ceiling-mounted speaker 710. Such examples are described in further detail below with reference to FIGS. 9-10. As another example, a printed circuit board 122 is shown as positioned in or adjacent to a duct 702 and configured to control an actuator configured to adjust a position of a damper in the duct. FIG. 7 illustrates some of the many possible arrangements of printed circuit boards 122 in air handling spaces consistent with the present disclosure.

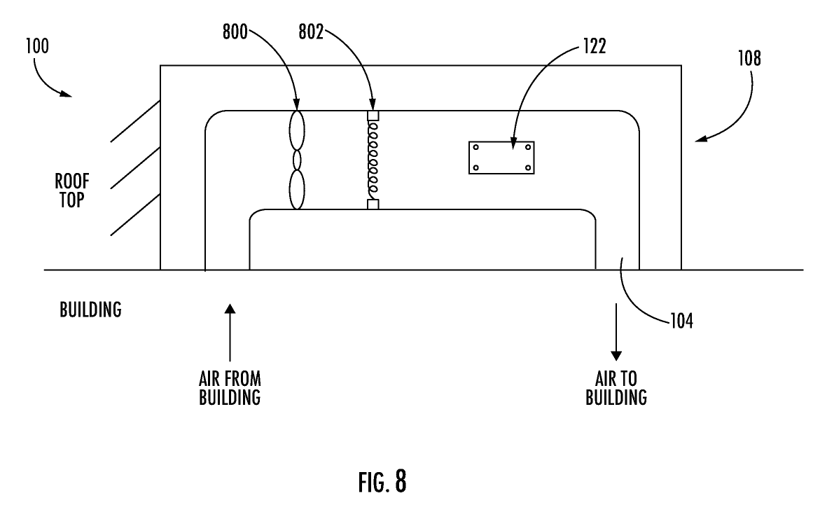

Referring now to FIG. 8, a diagram of a rooftop unit 108 (i.e., an example of HVAC equipment 108) is shown, according to an exemplary embodiment. The rooftop unit 108 is located on a roof of the building 100. The roof top unit 108 includes an air handling space 104. The air handling space 104 is communicable with ductwork and/or other air handling spaces 104 of the building 100 to receive air (return air) from the building 100 and to provide air (e.g., heated air, cooled air) to the building. As shown in FIG. 8, a fan 800 and a heat exchanger 802 are positioned in the air handling space 104. The fan 800 is operable to draw air into the roof top unit 108 from the building 100 and force air across the heat exchange 802, through the air handling space 104, and into the building 100.

FIG. 8 also shows a printed circuit board 122 positioned in the air handling space 104. In the example shown, the printed circuit board 122 is configured as a controller for the fan 800 and/or other controllable components of the rooftop unit 108. The printed circuit board 122 is mounted in the air handling space 104 such that the printed circuit board 122 is exposed to airflow through the air handling space 104 (i.e., without a case, enclosure, barrier, etc.). The reduced smoke-release properties of the printed circuit boards 122 as described above make such an arrangement possible, without compromising visibility in occupied spaces of the building in the event of a fire at the roof top unit 108.

Referring now to FIG. 9, a diagram showing electronics with metal enclosures is shown, according to an exemplary embodiment. FIG. 9 shows an air handling space 104 defined as a volume between a drop ceiling 706 and a structural ceiling 705. In the example shown, a first electronic device 950 is mounted within the air handling space. The first electronic device 950 may be a controller, a networking device, or some other electronic device. The first electronic device 950 includes a printed circuit board 122 at least partially enclosed in a metal enclosure 900.

FIG. 9 also shows a speaker 710 mounted on the drop ceiling 706 and at least partially disposed within the air handling space 104. In other embodiments, the speaker device 710 may be a lighting device (e.g., a light fixture), a camera, a sensor, etc. The speaker 710 includes a printed circuit board 122 and a metal enclosure 900 that at least partially encloses the printed circuit board 122. In the example shown, the metal enclosure 900 shields the printed circuit board 122 from exposure to airflow in the air handling space 104. Such arrangements are possible with the various printed circuit boards 122 described herein.

Referring now to FIG. 10, a diagram showing electronics with plastic enclosures is shown, according to an exemplary embodiment. FIG. 10 shows an air handling space 104 defined as a volume between a drop ceiling 706 and a structural ceiling 705. In the example shown, a first electronic device 1050 is mounted within the air handling space. The first electronic device 1050 may be a controller, a networking device, or some other electronic device. The first electronic device 1050 includes a printed circuit board 122 at least partially enclosed in a plastic enclosure 1000.

FIG. 10 also shows a speaker 710 mounted on the drop ceiling 706 and at least partially disposed within the air handling space 104. In other embodiments, the speaker device 710 may be a lighting device (e.g., a light fixture, a camera, a sensor, etc.). The speaker 710 includes a printed circuit board 122 and a plastic enclosure 1000 that at least partially encloses the printed circuit board 122. In the example shown, the plastic enclosure 1000 shields the printed circuit board 122 from exposure to airflow in the air handling space 104. Such arrangements are possible with the various printed circuit boards 122 described herein.

Referring now to FIG. 11, a diagram showing electronics mounted in an air handling space 104 without enclosures is shown, according to an exemplary embodiment. FIG. 11 shows an air handling space 104 defined as a volume between a drop ceiling 706 and a structural ceiling 705. In the example shown, a printed circuit board 122 is mounted within the air handling space such that the printed circuit board 122 is at least partially exposed to airflow in the air handling space 104. In various embodiments, the printed circuit board 122 is configured as a controller, a networking device, or some other electronic device.

FIG. 11 also shows a speaker 710 mounted on the drop ceiling 706 and at least partially disposed within the air handling space 104. In other embodiments, the speaker device 710 may be a lighting device (e.g., a light fixture, a camera, a sensor, etc.). The speaker 710 includes a printed circuit board 122. The speaker 710 is positioned and configured such that the printed circuit board 122 of the speaker 710 is at least partially exposed to airflow in the air handling space 104. In the embodiment of FIG. 11, the speaker 710 does not include a case or enclosure as in other embodiments described herein. Such a design may be cheaper and more environmentally-friendly to manufacturer relative to designs that include enclosures. The reduced smoke-release properties of the printed circuit boards 122 as disclosed herein allow for the printed circuit board 122 to be exposed to the air handling space 104 without creating dangers relating to smoke release in the case of a fire in the building 100.

The systems and methods described herein thereby facilitate improved smoke-reduction for electronic devices mounted in air handling spaces. For example, to achieve reduced smoke released during a building fire, a non-halogen flame retardant can be integrated into a printed circuit board, the printed circuit board can be installed in an electronic device, and the electronic device can be installed in an air handling space. In some cases, the electronic device may be configured such that the printed circuit board is at least partially exposed to airflow in the air handling space. Using the printed circuit board materials, coatings, etc. described above, such arrangement allows for a safe smoke release in a building fire with or without use of the enclosures or other designs currently required by building safety standards. Accordingly, in order to ensure building safety, standards organizations may feel compelled to replace the current standards and tests with new standards and tests that contemplate the systems and methods described herein.

### CONFIGURATION OF EXEMPLARY EMBODIMENTS

Other arrangements and combinations of the elements described herein and shown in the Figures are also contemplated by the present disclosure. The construction and arrangement of the systems and apparatuses as shown in the various exemplary embodiments are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.). For example, the position of elements can be reversed or otherwise varied and the nature or number of discrete elements or positions can be altered or varied. Accordingly, all such modifications are intended to be included within the scope of the present disclosure. Other substitutions, modifications, changes, and omissions can be made in the design, operating conditions and arrangement of the exemplary embodiments without departing from the scope of the present disclosure.

What is claimed is:

1. A method for reducing smoke in a building fire, comprising:
integrating a non-halogen flame retardant into a printed circuit board;
installing the printed circuit board in an electronic device; and
installing the electronic device in an air handling space.

2. The method of claim 1, wherein the non-halogen flame retardant comprises phosphorous.

3. The method of claim 1, comprising at least partially covering the printed circuit board in an intumescent coating.

4. The method of claim 1, comprising at least partially surrounding the printed circuit board with intumescent sheets.

5. The method of claim 1, wherein installing the electronic device in the air handling space comprises positioning the printed circuit board in the air handling space such that the printed circuit board is exposed to airflow in the air handling space.

6. The method of claim 1, wherein installing the printed circuit board in an electronic device comprises placing the printed circuit board in a plastic enclosure.

7. The method of claim 1, wherein the electronic device is a lighting device.

8. The method of claim 1, comprising:
establishing communication between the electronic device and HVAC equipment;
operating the electronic device to control the HVAC equipment.

9. The method of claim 1, wherein the electronic device comprises one or more of a lighting device, an HVAC device, a security device, a fire device, a speaker, or a camera.

10. The method of claim 1, wherein the air handling space is within a rooftop unit of an HVAC system.

11. The method of claim 1, wherein the air handling space is above a drop ceiling or below a raised floor.

12. A method for reducing smoke in a building fire, comprising:
obtaining a printed circuit board, wherein the printed circuit board comprises a non-halogen frame retardant or is at least partially covered with an intumescent coating or an intumescent sheet;
configuring circuitry components of the printed circuit board to perform one or more operations relating to a building; and
installing the printed circuit board in an air handling space.

13. The method of claim 12, comprising operating the circuitry components of the printed circuit board to perform the operations.

14. The method of claim 12, wherein the one or more operations comprise controlling, by the printed circuit board, HVAC equipment.

15. The method of claim 12, wherein the one or more operations comprise providing, by the printed circuit board, wireless network connectivity to user devices in a space proximate the air handling space.

16. The method of claim 12, wherein the one or more operations comprise controlling, by the printed circuit board, at least one of a speaker to emit a sound or a light fixture to emit a light.

17. The method of claim 12, wherein installing the printed circuit board in the air handling space comprises positioning the printed circuit board such that the printed circuit board is at least partially exposed to airflow in the air handling space.

18. The method of claim 12, wherein the printed circuit board is at least partially surrounded with a plurality of intumescent sheets.

19. A system, comprising:
an air handling space; and
a printed circuit board at least partially exposed to airflow in the air handling space, the printed circuit board comprising at least one of a non-halogen flame retardant, an intumescent coating, or an intumescent sheet.

20. The system of claim 19, wherein:
the system comprises a drop ceiling and an electronic device coupled to the drop ceiling;
the air handling space is at least partially bounded by the drop ceiling; and
the printed circuit board is configured to facilitate operation of the electronic device.
